(19) United States
(12) Patent Application Publication
(10) Pub. No.: US 2014/0124953 A1
(43) Pub. Date: May 8, 2014

(54) MULTI-CHIP SEMICONDUCTOR APPARATUS

(71) Applicant: SK hynix Inc., Icheon-si (KR)

(72) Inventors: Byung Deuk JEON, Icheon-si (KR); Nam Pyo HONG, Icheon-si (KR)

(73) Assignee: SK hynix Inc., Icheon-si (KR)

(21) Appl. No.: 14/152,679

(22) Filed: Jan. 10, 2014

(30) Foreign Application Priority Data
Mar. 23, 2012 (KR) 10-2012-0029948

(51) Int. Cl. H01L 25/065; H01L 23/538

(52) U.S. Cl. CPC H01L 25/0657; H01L 23/5384
USPC 257/774

(57) ABSTRACT

A multi-chip semiconductor apparatus includes a plurality of semiconductor chips electrically connected and stacked. Each of the semiconductor chips trims a voltage level used in the semiconductor chip in response to a chip select signal.

### CROSS-REFERENCES TO RELATED APPLICATION

The present application claims priority under 35 U.S.C. §119(a) to Korean application number 10-2012-0029948 filed on Mar. 23, 2012, in the Korean Intellectual Property Office, which is incorporated by reference herein in its entirety.

### BACKGROUND

1. Technical Field

The present invention relates to a multi-chip semiconductor apparatus, and more particularly, to a voltage generation circuit of a multi-chip semiconductor apparatus.

2. Related Art

In order to highly integrate a semiconductor apparatus, a variety of multi-chip packaging methods have been proposed. In particular, a chip stack method which stacks a plurality of semiconductor chips to form one semiconductor apparatus is widely used.

A plurality of semiconductor chips stacked in a multi-chip semiconductor apparatus are selected by a chip select signal, and operate independently of each other. The plurality of semiconductor chips are electrically connected to each other such that a processor for controlling operation of the semiconductor apparatus controls the respective semiconductor chips. Recently, a through-chip via has been used to commonly transfer a signal to a plurality of semiconductor chips. In general, since a semiconductor chip is fabricated using a silicon wafer, the through-chip via is referred to as a through-silicon via (TSV).

Meanwhile, each of the semiconductor chips inside the multi-chip semiconductor apparatus receives a voltage required for the operation of the semiconductor chip. The semiconductor chip uses the received voltage as it is, or adjusts the received voltage to a desired level.

FIG. 1 is a block diagram illustrating a voltage generation circuit of a conventional multi-chip semiconductor apparatus.

The multi-chip semiconductor apparatus including a plurality of semiconductor chips CHIP1 to CHIP4 stacked therein is positioned over a processor. The multi-chip semiconductor apparatus is connected to the processor through pads PAD. FIG. 1 illustrates a multi-chip semiconductor apparatus in which a plurality of semiconductor chips are electrically connected to each other through TSVs.

The semiconductor chips CHIP1 to CHIP4 include voltage generation circuits for generating voltages required for the respective semiconductor chips. The voltage generation circuits of the semiconductor chips CHIP1 to CHIP4 include reference voltage generation units 11 to 41 and internal voltage generation units 14 to 44, respectively. The reference voltage generation units 11 to 41 are configured to generate reference voltage VREF1 to VREF4 having a constant level, respectively, regardless of a change in a power supply voltage applied from outside. The internal voltage generation units 14 to 44 are configured to use the reference voltages VREF1 to VREF4 to generate internal voltages VINT1 to VINT4, respectively. The internal voltage generation units 14 to 44 compare feedback voltages obtained by dividing the internal voltages VINT1 to VINT4 to the reference voltages VREF1 to VREF4 and adjusting the internal voltage levels VINT1 to VINT4 according to the comparison result such that the level of the internal voltages VINT1 to VINT4 are constantly maintained. That is, when the voltage levels of the internal voltages VINT1 to VINT4 become lower or higher than a target level, the internal voltage generation units 14 to 44 perform an internal operation such that the voltage levels may approach the target level.

However, in the conventional multi-chip semiconductor apparatus having a stacked structure of semiconductor chips as illustrated in FIG. 1, the signal transfer path from the processor to the semiconductor chip CHIP4 at the upper most layer of the stacked semiconductor chips CHIP1 to CHIP4 may be longer than the signal transfer path to semiconductor chip CHIP1 positioned at the lowermost layer. Thus, signals received by the semiconductor chip CHIP4 may be delayed in comparison to signals received by the semiconductor chip CHIP1. Therefore, generation of data and data strobe signals is delayed. That is, since a signal transfer rate between the processor and the semiconductor memory chip at the uppermost layer decreases, a yield drop problem may occur.

### SUMMARY

In one embodiment of the present invention, a multi-chip semiconductor apparatus includes a plurality of semiconductor chips electrically connected and stacked. Each of the semiconductor chips trims a voltage level used in the semiconductor chip in response to a chip select signal.

In another embodiment of the present invention, a multi-chip semiconductor apparatus includes a plurality of semiconductor chips stacked and electrically connected by a through-chip via. Each of the semiconductor chips includes: a reference voltage generation unit configured to generate a reference voltage; a chip select signal generation unit configured to generate a plurality of chip select is signals in response to chip information; a voltage trimming unit configured to generate a trimming reference voltage by trimming the level of the reference voltage according to the plurality of chip select signals; and an internal voltage generation unit configured to generate an internal voltage in response to the level of the trimming reference voltage.

In another embodiment of the present invention, a multi-chip semiconductor apparatus includes a master chip and a plurality of slave chips which are electrically connected and stacked. Each of the slave chips receives a reference voltage and a chip select signal, which are generated by the master chip, and independently generates an internal voltage by trimming the reference voltage in response to the chip select signal.

In another embodiment of the present invention, a multi-chip semiconductor apparatus includes a master chip and a plurality of slave chips, which are stacked and electrically connected by a through-chip via. The master chip includes: a reference voltage generation unit configured to generate a reference voltage; and a chip select signal generation unit configured to generate a plurality of chip select signals in response to chip information, and each of the slave chips includes: a voltage trimming unit configured to generate a trimming reference voltage by trimming the level of the reference voltage according to the plurality of chip select signals; and an internal voltage generation unit configured to generate an internal voltage in response to the level of the trimming reference voltage.

### BRIEF DESCRIPTION OF THE DRAWINGS

Features, aspects, and embodiments are described in conjunction with the attached drawings, in which:

FIG. 1 is a block diagram illustrating a voltage generation circuit of a conventional multi-chip semiconductor apparatus;

FIG. 2 is a block diagram illustrating a voltage generation circuit of a multi-chip semiconductor apparatus according to one embodiment of the present invention;

FIG. 3 is a circuit diagram of the voltage generation circuit included in semiconductor chips illustrated in FIG. 2; and

FIG. 4 is a block diagram illustrating a voltage generation circuit of a multi-chip semiconductor apparatus according to another embodiment of the present invention.

### DETAILED DESCRIPTION

Hereinafter, a multi-chip semiconductor apparatus according to the present invention will be described below with reference to the accompanying drawings through example embodiments.

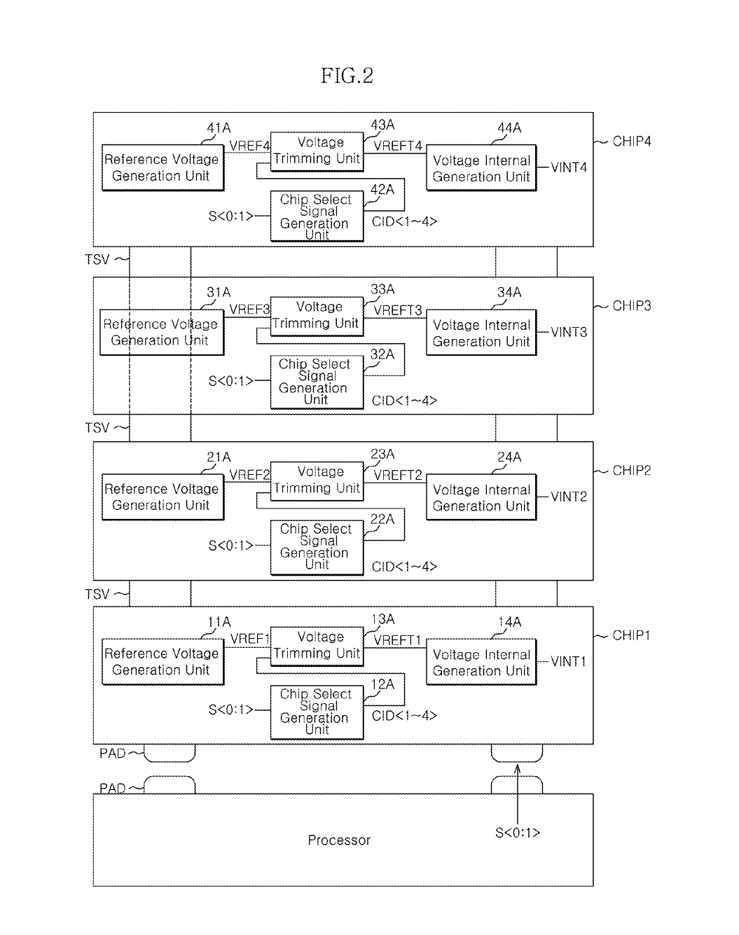

FIG. 2 is a block diagram illustrating a voltage generation circuit of a multi-chip semiconductor apparatus according to one embodiment of the present invention.

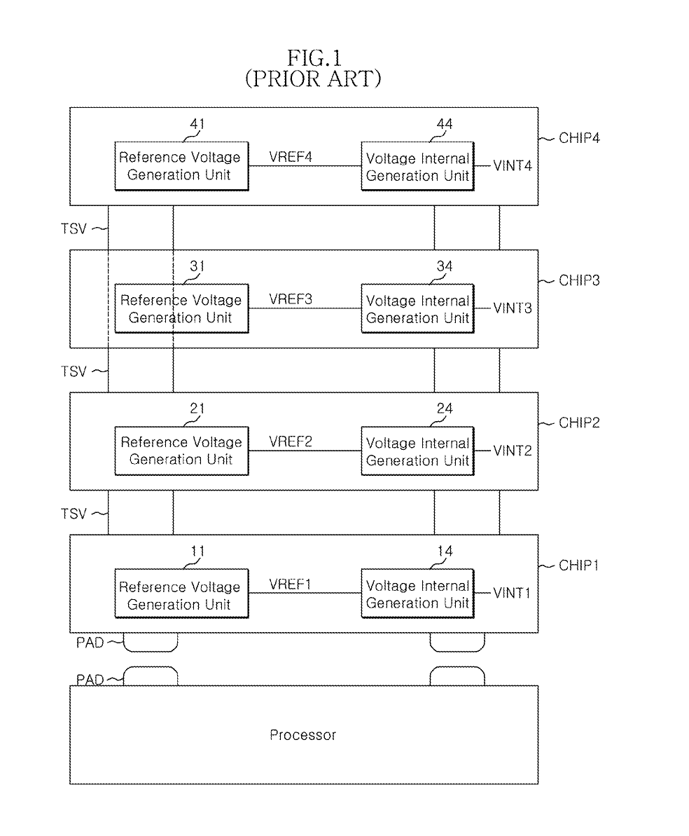

The multi-chip semiconductor apparatus including a plurality of semiconductor chips CHIP1 to CHIP4 stacked therein may be positioned over a processor. The multi-chip semiconductor apparatus is may be connected to the processor through pads PAD, and controlled by the processor. The processor may be an external processor, that is, external to the stack of semiconductor chips CHIP1 to CHIP4. FIG. 2 illustrates a multi-chip semiconductor apparatus in which a plurality of semiconductor chips are electrically connected to each other through TSVs. In general, a semiconductor apparatus includes a large number of TSVs formed therein. However, FIG. 1 illustrates only a part of the TSVs of the multi-chip semiconductor apparatus.

The plurality of semiconductor chips CHIP1 to CHIP4 according to this embodiment of the present invention may include voltage generation circuits for generating voltages required for the respective semiconductor chips. The voltage generation circuits of the semiconductor chips CHIP1 to CHIP4 include reference voltage generation units 11A to 41A, chip select signal generation units 12A to 42A, voltage trimming units 13A to 43A, and internal voltage generation units 14A to 44A, respectively. Since the plurality of semiconductor chips CHIP1 to CHIP4 are configured in a substantially similar manner, the internal operation and internal circuits of the first semiconductor chip CHIP1 will be representatively described in detail.

The first semiconductor chip CHIP1 includes the reference voltage generation unit 11A, the chip select signal generation unit 12A, the voltage trimming unit 13A, and the internal voltage generation unit 14A.

The reference voltage generation unit 11A is configured to generate a reference voltage VREF1 having a constant level is regardless of a change in a power supply voltage, just as the conventional multi-chip semiconductor apparatus. The power supply voltage may come from a source external to the semiconductor chips CHIP1 to CHIP4 through a pad and a TSV allocated to receive and transmit the power supply voltage.

The chip select signal generation unit 12A is configured to receive chip information S<0:1> through a TSV from the processor, and the chip select signal generation unit 12A may activate any one of a plurality of chip select signals CID<1˜4> corresponding to the respective semiconductor chips CHIP1 to CHIP4 by decoding the received chip information S<0:1>. Because the semiconductor chips CHIP1 to CHIP4 are sequentially stacked over the processor, each of the chip select signals CID<1˜4> has information about a distance from the processor to the semiconductor chip CHIP1 to CHIP4 corresponding to the chip select signal CID<1˜4>.

The voltage trimming unit 13A is configured to trim the level of the reference voltage VREF1 according to the plurality of chip select signals CID<1˜4> and generate a trimming reference voltage VREFT1. The levels of the trimming reference voltages VREFT1 to VREFT4 of the respective semiconductor chips CHIP1 to CHIP4 may differ according to the distance information contained in the chip select signals CID<1˜4>. For example, as the distance increases from the processor to the semiconductor chip CHIP1 to CHIP4 corresponding to the chip select signal CID<1˜4>, the reference voltage may be trimmed to a higher level. In other words, the voltage level to which the reference voltage VREF1 is trimmed may increase as the distance between the processor and the semiconductor chip CHIP1 to CHIP4 corresponding to one of the chip select signals CID<1˜4> increases. For example, semiconductor chip CHIP2 may trim the reference voltage to a higher level than semiconductor chip CHIP1 because semiconductor CHIP2 is farther from the processor than semiconductor CHIP1. Similarly, semiconductor chip CHIP3 may trim the reference voltage to a higher level than semiconductor chip CHIP2.

The internal voltage generation unit 14A may be implemented according to conventional technology. For example, the internal voltage generation unit 14A may receive the trimming reference voltage VREFT1 and generate the internal voltage VINT1 by regulating or charge-pumping the received trimming reference voltage VREFT1. Because the levels of the trimming reference voltages VREFT1 to VREFT4 differ according to the chip select signals CID<1˜4> corresponding to the respective semiconductor chips CHIP1 to CHIP4, the levels of the internal voltages VINT1 to VINT4 generated by the respective semiconductor chips CHIP1 to CHIP4 may differ. That is, as the distance from the processor increases, the internal voltage may be generated at a higher level.

In this embodiment of the present invention, when the voltage generation circuit is implemented to generate an internal voltage, an internal voltage is used as an example for purposes of explanation. The present invention, however, may also be applied to is a case in which the voltage generation circuit is implemented to provide an external voltage level to the respective chips.

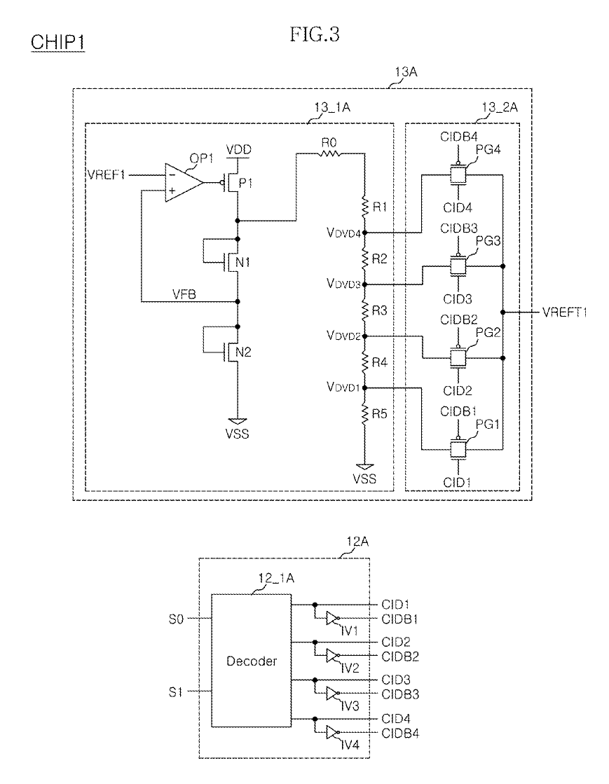

FIG. 3 is a circuit diagram of the internal voltage generation circuit of the first semiconductor chip CHIP1. Since the reference voltage generation unit 11A and the internal voltage generation unit 14A are configured in a similar manner as those of the conventional multi-chip semiconductor apparatus, the detailed descriptions thereof are omitted herein.

The chip select signal generation unit 12A includes a decoder 12_1A and a plurality of inverters IV1 to IV4. The chip select signal generation unit 12A provides a signal for activating a chip selected in the multi-chip semiconductor apparatus. Specifically, the decoder 12A_1A is configured to receive the chip information S<0:1> from the processor and generate the plurality of chip select signals CID<1˜4> by decoding the received chip information S<0:1>. Furthermore, the chip select signal generation unit 12A generates chip select signals CIDB<1˜4> having a level inverted through the plurality of inverters IV1 to IV4.

The voltage trimming unit 13A includes a voltage dividing section 13_1A and a voltage pass section 13_2A.

The voltage dividing section 13_1A is configured to receive the reference voltage VREF1 through the TSV, and generate a plurality of divided voltages VDVD1 to VDVD4. Specifically, the voltage dividing section 13_1A includes a first comparator OP1, a first PMOS transistor P1, first and second NMOS transistors N1 and N2, a is reference resistor R0, and a plurality of dividing resistors R1 to R5.

The first comparator OP1 is configured to compare the reference voltage VREF1 to a feedback voltage VFB. The first PMOS transistor P1 is configured to receive an external voltage VDD through a drain terminal thereof according to an output level of the first comparator OP1. The first and second NMOS transistors N1 and N2 are connected in a diode configuration between the first PMOS transistor P1 and a ground VSS and configured to generate the feedback voltage VFB by dividing a voltage.

The reference resistor R0 and the plurality of dividing resistors R1 to R5 are connected in series to the drain terminal of the first PMOS transistor P1. The resistors R0 to R5 divide the voltage of the drain terminal of the first PMOS transistor P1, and the resistors R0 to R5 may generate the divided voltages VDVD1 to VDVD4.

The voltage pass section 13_2A is configured to output any one of the divided voltages VDVD1 to VDVD4 as the trimming reference voltage VREFT1 in response to the activated chip select signals CID<1˜4>. Specifically, the voltage pass section 13_2A includes a plurality of pass gates PG1 to PG4 configured to pass any one of the divided voltages VDVD1 to VDVD4 as the trimming reference voltage VREFT1 in response to any one of the chip select signals CID<1˜4>. The respective pass gates PG1 to PG4 receive the chip select signals CID<1˜4> and the inverted chip select signals CIDB<1˜4> through gate terminals thereof. When the first chip select signal CID<1> is activated, the first semiconductor chip CHIP1 outputs the first divided voltage VDVD1 as the trimming reference voltage VREFT1. On the other hand, when the second to fourth chip select signals CID<2˜4> corresponding to the second to fourth semiconductor chips CHIP2 to CHIP4 are activated, the second to fourth semiconductor chips CHIP2 to CHIP4 output the second to fourth divided voltages VDVD2 to VDVD4 as the trimming reference voltages VREFT2 to VREFT4, respectively. Because the reference voltage VREF1 may be trimmed to a higher level as the distance from the processor to the semiconductor chip CHIP1 to CHIP4 increases, the voltage pass section 13_2A may output a higher level divided voltage VDVD1 to VDVD4 as the trimming reference voltage VREFT1 as the distance increases from the processor to the semiconductor chip CHIP1 to CHIP4.

Therefore, the voltage trimming unit 13A provides the divided voltages VDVD1 to VDVD4 stabilized by the voltage dividing section 13_1A, and outputs the first divided voltage VDVD1 as the trimming reference voltage VREFT1 when the first chip select signal CID<1> corresponding to the first semiconductor chip CHIP1 is activated. The second to fourth semiconductor chips CHIP2 to CHIP4 operate in the same manner as the first semiconductor chip CHIP1.

As a result, the first semiconductor chip CHIP1 generates the internal voltage VINT1 having a level corresponding to distance information contained in the first chip select signal CID<1>. Similarly, the second to fourth semiconductor chips CHIP2 to CHIP4 generate the internal voltages VINT2 to VINT4 having a level is corresponding to distance information contained in the chip select signals CID<2˜4>, respectively.

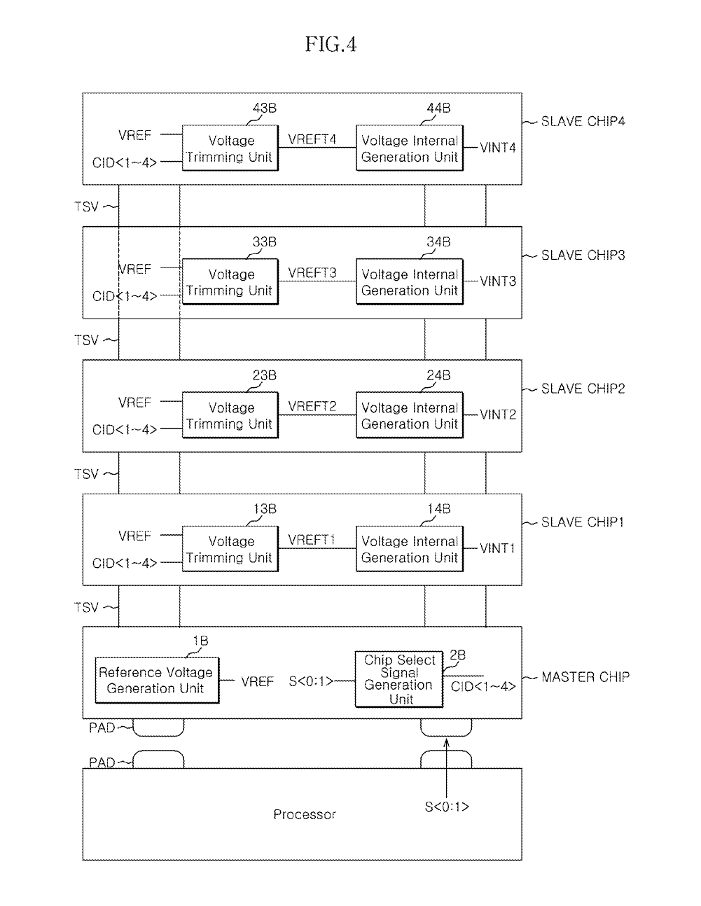

FIG. 4 is a block diagram illustrating a voltage generation circuit of a multi-chip semiconductor apparatus according to another embodiment of the present invention.

The multi-chip semiconductor apparatus including a plurality of semiconductor chips MASTER CHIP and SLAVE CHIP1 to SLAVE CHIP4 stacked therein is positioned over a processor. The multi-chip semiconductor apparatus is connected to the processor through pads PAD, and controlled by the processor. In this embodiment of the present invention, the semiconductor apparatus includes a master chip MASTER CHIP and a plurality of slave chips SLAVE CHIP1 to SLAVE CHIP4. The master chip MASTER CHIP and the plurality of slave chips SLAVE CHIP1 to SLAVE CHIP4 are vertically stacked, and electrically connected to each other through TSVs. The multi-chip semiconductor apparatus may include a large number of TSVs, but FIG. 4 illustrates only a few of the TSVs.

The master chip MASTER CHIP is configured to perform an operation of exchanging signals with the processor positioned outside the stack comprising the master chip MASTER CHIP and the slave chips SLAVE CHIP1 to SLAVE CHIP4, and the master chip MASTER CHIP may control the slave chips SLAVE CHIP1 to SLAVE CHIP4. Furthermore, the respective slave chips SLAVE CHIP1 to SLAVE CHIP4 may be configured to perform a specific operation according to control of the master chip MASTER CHIP. For example, the master chip MASTER CHIP includes peripheral circuits related to signal input/output and a control signal, and the slave chips SLAVE CHIP1 to SLAVE CHIP4 include memory banks for storing data. For reference, the configuration of circuits allocated to the master chip MASTER CHIP and the slave chips SLAVE CHIP1 to SLAVE CHIP4 may be changed, if necessary.

In this embodiment of the present invention, the master chip MASTER CHIP includes a reference voltage generation unit 1B and a chip select signal generation unit 2B.

The reference voltage generation unit 1B is configured to generate a reference voltage VREF and transmit the generated reference voltage VREF to the slave chips SLAVE CHIP1 to SLAVE CHIP4 through a TSV.

The chip select signal generation unit 2B is configured to receive chip information S<0:1> through a pad PAD from the processor, and activate any one of a plurality of chip select signals CID<1˜4> corresponding to the slave chips SLAVE CHIP1 to SLAVE CHIP4 by decoding the chip information S<0:1>. Because the slave chips SLAVE CHIP1 to SLAVE CHIP4 are sequentially stacked over the processor, each of the chip select signals CID<1˜4> has information about the distance from the processor. The plurality of chip select signals CID<1˜4> are transmitted to the respective slave chips SLAVE CHIP1 to SLAVE CHIP4 through the TSV.

The slave chips SLAVE CHIP1 to SLAVE CHIP4 independently include voltage generation circuits for generating voltages used in the respective chips. Specifically, the slave chips SLAVE CHIP1 to SLAVE CHIP4 include voltage trimming units 13B to 43B and internal voltage generation units 14B to 44B, respectively. Since the slave chips SLAVE CHIP1 to SLAVE CHIP4 are configured in a substantially similar manner, the configuration and operation of the first slave chip SLAVE CHIP1 will be representatively described in detail.

The first slave chip SLAVE CHIP1 includes the voltage trimming unit 13B and the internal voltage generation unit 14B.

The voltage trimming unit 13B is configured to generate a trimming reference voltage VREFT1 by trimming the level of the reference voltage VREF1 according to the plurality of chip select signals CID<1˜4>. The levels of the trimming reference voltages VREFT1 to VREFT4 of the slave chips SLAVE CHIP1 to SLAVE CHIP4 differ according to the distance information contained in the chip select signals CID<1˜4>. That is, as the distance from the processor increases, the reference voltage VREF is trimmed to a higher level.

The voltage trimming unit 13B is configured in a substantially similar manner as the voltage trimming unit 13A illustrated in FIG. 3. Thus, when the first chip select signal CID<1> corresponding to the first salve chip SLAVE CHIP1 is activated, the voltage trimming unit 13B outputs the first divided voltage VDVD1 as the trimming reference voltage VREFT1. The second to fourth slave chips SLAVE CHIP2 to SLAVE CHIP4 operate in a substantially similar same manner as the first slave chip CHIP1.

As a result, the first slave chip SLAVE CHIP1 generates an is internal voltage VINT1 having a level corresponding to the distance information contained in the first chip select signal CID<1>. Similarly, the second to fourth slave chips SLAVE CHIP2 to SLAVE CHIP4 generate internal voltages VINT2 to VINT4 having a level corresponding to the distance information contained in the chip select signals CID<2˜4>.

The internal voltage generation unit 14B may be implemented according to conventional technology. For example, the internal voltage generation unit 14B may receive the trimming reference voltage VREFT1 and generate the internal voltage VINT1 by regulating or charge-pumping the received trimming reference voltage VREFT1. Because the levels of the trimming reference voltages VREFT1 to VREFT4 differ according to the chip select signals CID<1˜4> corresponding to the respective slave chips SLAVE CHIP1 to SLAVE CHIP4, the levels of the internal voltages VINT1 to VINT4 generated by the respective slave chips SLAVE CHIP1 to SLAVE CHIP4 may differ. That is, as the distance from the processor increases, the internal voltage may be generated at a higher level.

While certain embodiments have been described above, it will be understood to those skilled in the art that the embodiments described are by way of example only. Accordingly, the multi-chip semiconductor apparatus described herein should not be limited based on the described embodiments. Rather, the multi-chip semiconductor apparatus described herein should only be limited in light of the claims that follow when taken in conjunction with the is above description and accompanying drawings.

What is claimed is:

1. A multi-chip semiconductor apparatus comprising a plurality of semiconductor chips stacked and electrically connected by a through-chip via,
wherein each of the semiconductor chips comprises:
a reference voltage generation unit configured to generate a reference voltage;
a chip select signal generation unit configured to generate a plurality of chip select signals in response to chip information;
a voltage trimming unit configured to generate a trimming reference voltage by trimming a level of the reference voltage according to the plurality of chip select signals; and
an internal voltage generation unit configured to generate an is internal voltage in response to a level of the trimming reference voltage.

2. The multi-chip semiconductor apparatus according to claim 1, wherein the chip information is applied from an external processor.

3. The multi-chip semiconductor apparatus according to claim 2, wherein each of the chip select signals has information on a distance from the processor to one of the semiconductor chips corresponding to the one of the plurality of chip select signals.

4. The multi-chip semiconductor apparatus according to claim 3, wherein the chip select signal generation unit comprises a decoder configured to decode the chip information into the plurality of chip select signals.

5. The multi-chip semiconductor apparatus according to claim 3, wherein the voltage trimming unit comprises:
a voltage dividing section configured to receive the reference voltage through the through-chip via and generate a plurality of divided voltages using a plurality of dividing resistors; and
a voltage pass section configured to output any one of the divided voltages as the trimming reference voltage in response to an activated chip select signal.

6. The multi-chip semiconductor apparatus according to claim 5, wherein the voltage pass section comprises a plurality of pass gates configured to pass any one of the divided voltages as the trimming reference voltage in response to any one of the chip select signals.

7. The multi-chip semiconductor apparatus according to claim 6, wherein the voltage pass section outputs a higher level divided voltage as the trimming reference voltage, as the distance from the processor increases.
